(19) United States
(12) Patent Application Publication
(10) Pub. No.: US 2026/0276171 A1
(43) Pub. Date: Sep. 17, 2026

(54) LIGHTING DEVICE WITH EMBEDDED ELECTRONICS

(71) Applicant: OSRAM GmbH, Muenchen (DE)

(72) Inventors: Andreas Kampfrath, Niederstotzingen (DE); Albert Heinrich, Giengen (DE); Kilian Erath, Aalen (DE); Juergen Beck, Gerstetten/Heuchling (DE); Stefan Schwedhelm, Ulm (DE); Nico Irmler, Karlsbad (DE); Andreas Jungnickl, Muenchen (DE)

(21) Appl. No.: 19/162,618

(22) PCT Filed: Mar. 7, 2024
(86) PCT No.: PCT/EP2024/055982

§ 371 Date: Sep. 5, 2025

(30) Foreign Application Priority Data
Mar. 9, 2023 (DE) 10 2023 105 944.0

(51) Int. Cl. F21S 45/47; F21S 43/14

(52) U.S. Cl. CPC F21S 45/47; F21S 41/194; F21S 43/14; F21S 43/195

(57) ABSTRACT

In an embodiment a lighting device includes a semiconductor light source arrangement arranged on a carrier, electronics configured for operating the semiconductor light source arrangement, a heat sink configured for cooling the semiconductor light source arrangement, an electrical connection element configured for supplying power to the semiconductor light source arrangement, a thermally conductive layer, and a holder, wherein the carrier is arranged in a first recess of the holder, wherein the heat sink forms at least one surface in the first recess, which is substantially parallel to the carrier, and wherein the electronics are arranged on a side of the carrier opposite the semiconductor light source arrangement and are embedded in the thermally conductive layer between the carrier and the holder and/or the heat sink in the first recess.

### CROSS-REFERENCE TO RELATED APPLICATIONS

This patent application is a national phase filing under section 371 of PCT/EP 2024/055982, filed Mar. 7, 2024, which claims the priority of German patent application no. 10 2023 105 944.0, filed Mar. 9, 2023, each of which is incorporated herein by reference in its entirety.

### TECHNICAL FIELD

The invention relates to a lighting device, in particular a lighting device suitable for use in motor vehicles, and a method for manufacturing such a lighting device.

### BACKGROUND

A lighting device is disclosed, for example, in WO 2013/079302 A1. This document describes a lighting device/motor vehicle headlight that has a semiconductor light source arrangement, a housing, a heat sink for cooling the semiconductor light source arrangement, and an electrical connection element for supplying power to the semiconductor light source arrangement.

However, known lighting devices often have the disadvantage that water penetrating into the lighting device damages the electronics for operating the semiconductor light source arrangement or leads to electrochemical migration. This is a known problem, particularly in vehicle lights such as rear lights or combined rear lights (RCL), fog lights, or front lights.

In order to reduce the ingress of moisture or to protect the electronics from ingress of moisture, in known lighting devices, for example, the electronics are encapsulated with a casting material in a further step, a coating (conformal coating) is applied to the electronics, or the electronics are encapsulated by an additional cover.

However, these options all require an additional step to protect the electronics from moisture, which means more work to make the lighting devices and higher manufacturing costs.

### SUMMARY

Embodiments provide a lighting device that offers an improved means of protecting electronics for operating a semiconductor light source arrangement in the lighting device from moisture penetration. Further embodiments provide a method for manufacturing such a lighting device.

Embodiments propose a lighting device in which the electronics for operating a semiconductor light source arrangement in the lighting device are located on a side of a carrier opposite the semiconductor light source arrangement, e.g. mounting board, and the electronics are embedded in a thermally conductive layer between the carrier and a holder and/or a heat sink of the lighting device in order to protect them from moisture penetration. The thermally conductive layer may perform the task of thermally coupling the carrier to the heat sink and can also perform the task of mechanically coupling the carrier to the holder or heat sink in the form of a thermally conductive adhesive.

Embedding the electronics eliminates the need for additional conformal coating of the electronics as a further process step after inserting the carrier into the holder, while at the same time providing excellent protection against electrochemical migration. Arranging the electronics on the side of the carrier opposite the semiconductor light source array also results in an immense gain of space on the top (LED side) of the carrier, thus enabling a greater variety of products to be achieved in a “ ” manner. For example, more or larger light sources can be placed on the top of the carrier. In a specific case, it is possible, for example, to place bi-or tri-color modules on the top side of the carrier, or, in the case of use for a front headlight, a (small) matrix light module can possibly be placed on the top side of the carrier.

Another advantage of the arrangement according to the invention is that disruptive components on the upper side of the carrier are eliminated, allowing better coupling of a light guide to the semiconductor light source arrangement because a smaller distance between the light guide and the semiconductor light source arrangement is possible. This allows for better light output at the interface between the light guide and the semiconductor light source arrangement and thus also better light output of the lighting device in general.

Another advantage of inserting/pressing the electronics into the thermally conductive layer is that the thermally conductive layer does not need to be as thick. The layer thickness does not need to be much thicker than the highest component of the electronics arranged on the carrier. This results in a shorter heat path from the electronics to the heat sink compared to modules in which, for example, the entire electronics are inserted into a housing (e.g., a tube) and then encapsulated.

Furthermore, in the automotive sector (automotive industry), the requirements for electromagnetic compatibility (EMC) of the individual components in the vehicle are very high. The lighting device according to the invention has the advantage in this respect that, by arranging the electronics on the side of the carrier opposite the semiconductor light source arrangement and by embedding the electronics in the thermally conductive layer, the carrier, the mounting and the thermally conductive layer already provide improved electromagnetic radiation characteristics, so that fewer or no additional precautions need to be taken to meet the EMC requirements in the automotive sector.

A lighting device according to a first aspect comprises a semiconductor light source arrangement arranged on a carrier, electronics for operating the semiconductor light source arrangement, a heat sink for cooling the semiconductor light source arrangement, an electrical connection element for supplying power to the semiconductor light source arrangement, and a holder. The carrier is arranged in a first recess of the holder and the heat sink forms at least one surface in the first recess that is essentially parallel to the carrier.

The lighting device is characterized in that the electronics are arranged on a side of the carrier opposite the semiconductor light source arrangement, and in that the electronics are embedded in a thermally conductive layer between the carrier and the holder and/or the heat sink in the first recess. In particular, the electronics are completely surrounded by the thermally conductive layer.

In some embodiments, the carrier and/or the electronics are thermally coupled to the heat sink via the thermally conductive layer. This allows heat generated in the semiconductor light source arrangement and the electronics during operation of the lighting device to be dissipated to the heat sink. The heat sink can be designed in particular so that it absorbs the heat generated in the semiconductor light source arrangement and the electronics and dissipates it to the environment or to a medium surrounding the heat sink.

In some embodiments, the holder and/or the heat sink comprises at least one projection on which the carrier rests at least partially. For example, the holder may comprise a circumferential projection/edge in the region of the first recess, on which the carrier rests at least partially. This circumferential projection/edge may also be interrupted in sections to ensure that excess material of the thermally conductive layer can escape when the carrier is pressed onto the thermally conductive layer. Alternatively, or in addition to this, the heat sink may comprise at least one projection/bulge formed within the first recess and in the direction of the carrier, on which the carrier rests at least partially. Alternatively or in addition, the heat sink, formed within the first recess and in the direction of the carrier, may comprise at least one projection/bulge on which the carrier rests at least partially. For example, the heat sink may comprise a central, e.g., cylindrical bulge on which the carrier rests at least partially.

The at least one projection of the holder and/or the heat sink can serve in particular to provide a bearing surface for the carrier and at the same time to define a height such that the electronics do not collide with the holder or the heat sink when the carrier is pressed onto the thermally conductive layer, which could lead to damage to the electronics. The position or height of the projection can be selected accordingly so that the electronics do not collide with the holder or the heat sink when the carrier is pressed onto the thermally conductive layer. If the protrusion/bulge is part of the heat sink, and optionally if the heat sink is made of metal, this bulge can also form a heat sink for the carrier and can optionally also be used, for example, to provide an electrical connection (ground potential) for the carrier.

In some embodiments, the holder and/or heat sink comprises at least a second recess in which the electronics are arranged. For example, the holder and/or heat sink can form, at least in some areas, a slightly spaced negative of the carrier with the electronics attached to it, so that the electronics arranged on the carrier are arranged in the corresponding recess(es) of the holder and/or heat sink. This allows, for example, the amount of material of the thermally conductive layer required to embed the electronics to be reduced, while still ensuring optimum thermal coupling between the electronics+carrier and the holder and/or heat sink. Such a design may be preferred in particular if the holder and the heat sink are made in one piece from a component, for example a plastic injection molded part, since in such a case it is easy to create a slightly spaced negative of the carrier with the electronics attached to it in the holder/heat sink.

In some embodiments, the thermally conductive layer has a thermal conductivity greater than or equal to 1.5 watts/(meter Kelvin) (W/mK), in particular greater than or equal to 5 W/mK. In particular, the material of the thermally conductive layer can be selected such that the thermally conductive layer has a thermal conductivity of at least 1.79 W/mK, or at least 2.3 W/mK, or at least 3.5 W/mK, or at least 5.0 W/mK, or at least 6.0 W/mK, or at least 9.2 W/mK, or at least 10.0 W/mK.

In some respects, the thermally conductive layer is free of silicone. Silicone-free thermal pastes have ideal thermal properties and ensure reliable heat dissipation over a longer period of time than most industrial, thermally conductive materials. Conventional silicone-containing thermal pastes, on the other hand, melt after several heating and cooling phases (known as the pump-out effect). This creates gaps and the pastes lose their effectiveness, causing the assemblies to overheat and leading to premature product failure. The thermally conductive layer is therefore designed to almost completely eliminate the pump-out effect and ensure long-lasting thermal management and effective heat conduction. The major advantages of this silicone-free thermally conductive layer are its long service life and functionality.

In some respects, the thermally conductive layer exhibits greater elasticity/viscosity in its cured state than an epoxy or polyurethane casting. In particular, the material of the thermally conductive layer can be selected so that it does not cure completely, but instead exhibits a certain degree of elasticity/viscosity on a permanent basis. This has the advantage that the electronics embedded in the thermally conductive layer are not damaged by a completely hardened casting in the event of voltages occurring within the lighting device. The thermally conductive layer, which is relatively elastic compared to an epoxy or polyurethane casting, can instead compensate for any voltages that may occur, at least to a certain extent.

In some embodiments, the heat sink comprises a first heat sink section which is arranged in the first recess of the holder and which forms the at least one surface which is substantially parallel to the carrier. In addition, the heat sink comprises a second heat sink section which is arranged to fit precisely between the holder and the electrical connection element. This can be achieved, for example, by injection molding the heat sink in a single step as, for example, an insert with the holder and the electrical connection element. Alternatively, the heat sink can be positioned to fit between the holder and the electrical connection element by plugging the holder and the electrical connection element together around at least the second heat sink section or by bonding them to the heat sink section.

In some embodiments, the electrical connection element is formed in one piece with the holder, in particular as a plastic injection molded part.

According to some embodiments, the heat sink is formed in one piece with the holder and optionally in one piece with the electrical connection element. For example, the holder may comprise the heat sink as a component and be formed together with the holder as a plastic injection molded part.

According to some embodiments, the electrical connection element comprises electrical contacts which are passed through the heat sink and electrically contact the carrier or conductor tracks located on the carrier. For example, the electrical contacts can form a press fit with openings provided for this purpose in the carrier of the lighting device.

In some embodiments, locking elements are arranged on the holder to form a bayonet lock with a socket, for example of a vehicle light. For example, the socket may be designed in accordance with a defined standard, and the locking elements may be designed to form a bayonet lock with the socket.

In some embodiments, the carrier is designed as a mounting board. This allows the components of the semiconductor light source arrangement to be easily mounted on a surface of the mounting board and electrically connected by conductor tracks. Alternatively, the carrier can also be designed as a conductor frame, also referred to below as a lead frame, in order to achieve the same advantages.

In some embodiments, the carrier is arranged with a clamping seat in a receptacle of the holder in the first recess or is held in place in some other way. Advantageously, the semiconductor light source arrangement and the electronics are arranged and pre-assembled on the carrier in such a way that the carrier can be manufactured as a self-contained module comprising the semiconductor light source arrangement and the electronics and then installed in the lighting device according to the invention.

The lighting device according to the invention is preferably designed as an LED retrofit and is intended for use in motor vehicles. Preferably, the lighting device according to the invention is compatible with incandescent lamps used in motor vehicles as rear lights, brake lights, indicator lights, position lights, or daytime running lights.

In addition, a method for manufacturing a lighting device is specified, in particular a lighting device according to the preceding embodiments. The method comprises providing a holder with a heat sink arranged in a first recess of the holder and an electrical connection element connected to the holder. The method further comprises applying a thermally conductive layer to an area of the holder and/or the heat sink within the first recess, and pressing a carrier with a semiconductor light source arrangement arranged on a first side of the carrier and electronics for operating the semiconductor light source arrangement arranged on a second side opposite the first side onto the thermally conductive layer. The pressing is carried out in such a way that the electronics are embedded in the thermally conductive layer between the carrier and the holder and/or the heat sink.

Pressing the carrier into the heat-conductive layer embeds the electronics in the heat-conductive layer, i.e., surrounds them. This ensures optimum heat conductivity between the electronics and the heat sink or holder. Pressing may also cause excess material from the thermally conductive layer to be pressed upward past the carrier, forming a protrusion of the thermally conductive layer on or next to the carrier.

The provision of the holder may comprise inserting a heat sink and, optionally, inserting electrical connections into a plastic injection mold, as well as injecting plastic material around the optional electrical connections and the heat sink in the mold in such a way that, after solidification, the plastic material forms the holder in whose material the optional electrical connections and the heat sink are fixed.

### BRIEF DESCRIPTION OF THE DRAWINGS

Further aspects and embodiments according to the proposed principle will become apparent from the various embodiments and examples described in detail in connection with the accompanying drawings.

FIG. 1 shows a perspective view of a lighting device according to the proposed principle;

FIG. 2 shows a perspective view of a further embodiment of a lighting device according to the proposed principle;

FIG. 3 shows a cross-section through a lighting device according to the proposed principle;

FIG. 4 shows a cross-section through a further embodiment of a lighting device according to the proposed principle; and

FIG. 5 shows a top view of a carrier according to the proposed principle.

### DETAILED DESCRIPTION OF ILLUSTRATIVE EMBODIMENTS

The following embodiments and examples show various aspects and combinations thereof according to the proposed principle. The embodiments and examples are not always to scale. Likewise, various elements may be enlarged or reduced in size to highlight individual aspects. It is understood that the individual aspects and features of the embodiments and examples shown in the figures can be readily combined with one another without compromising the principle of the invention. Some aspects comprise a regular structure or shape. It should be noted that in practice, minor deviations from the ideal shape may occur without contradicting the inventive idea.

Furthermore, the individual figures, features, and aspects are not necessarily shown in their correct size, and the proportions between the individual elements do not necessarily have to be correct. Some aspects and features are emphasized by being shown enlarged. However, terms such as “above,” “above,” “below,” “below,” “larger,” “smaller,” and the like are shown correctly in relation to the elements in the figures. This makes it possible to infer such relationships between the elements from the figures.

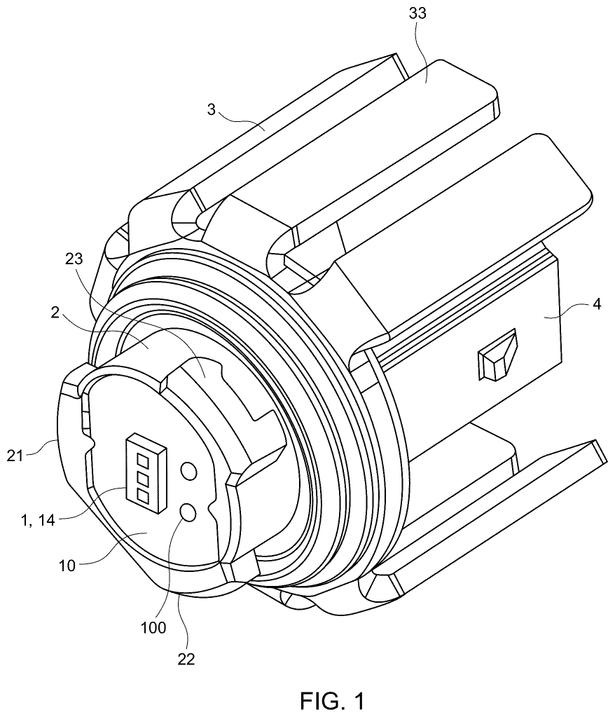

FIGS. 1 to 4 schematically show lighting devices according to the proposed principle.

The lighting devices comprise a semiconductor light source arrangement 1 arranged on a carrier 10, a heat sink 3 for cooling the semiconductor light source arrangement 1, an electrical connection element 4 comprising three electrical connections 41, 42, 43 for supplying power to the semiconductor light source arrangement 1, and a common holder 2 for the electrical connection element 4, the support 10, and the heat sink 3. The lighting devices are intended, for example, for use in motor vehicles to generate brake lights and tail lights.

The semiconductor light source arrangement 1 comprises a plurality of light-emitting diodes which are arranged together with electronics 13 for operating the light-emitting diodes on a mounting board 10. In the case shown, the semiconductor light source arrangement 1 comprises three light-emitting diodes, but the number three is to be understood here as merely exemplary, and the number of ‘light-emitting diodes may also be greater or less than three.

The mounting board 10 serves as a common carrier 10 for the light-emitting diodes of the semiconductor light source arrangement 1 and the electronics 13, wherein the semiconductor light source arrangement 1 is arranged on one side of the mounting board 10 and the electronics 13 is arranged on a side of the mounting board 10 opposite the semiconductor light source arrangement 1.

The light-emitting diodes and the electronics 13 are mounted on opposite surfaces of the mounting board 10 and are electrically connected to each other by conductor tracks or contact passages through the mounting board 10. The electronics 13 can be designed as a driver circuit, for example as a so-called linear driver, i.e. as a linear voltage regulator. The light-emitting diodes can emit red light during operation, for example. In the case shown, the three light-emitting diodes are arranged next to each other, whereas in the case of five light-emitting diodes, for example, four light-emitting diodes can be arranged at the corners of a fictitious square on the surface of the mounting board 10 and the fifth light-emitting diode can be arranged in the center of this fictitious square. The light-emitting diodes may be covered by a hemispherical, transparent dome 14, which is not explicitly shown, which is arranged on the surface of the mounting board 10 and serves as the primary optics and as protection for the light-emitting diodes. In the case of the five light-emitting diodes, the light-emitting diodes arranged at the corners of the fictitious square can, for example, serve together to generate a brake light, whereas the central light-emitting diode can serve to generate a tail light.

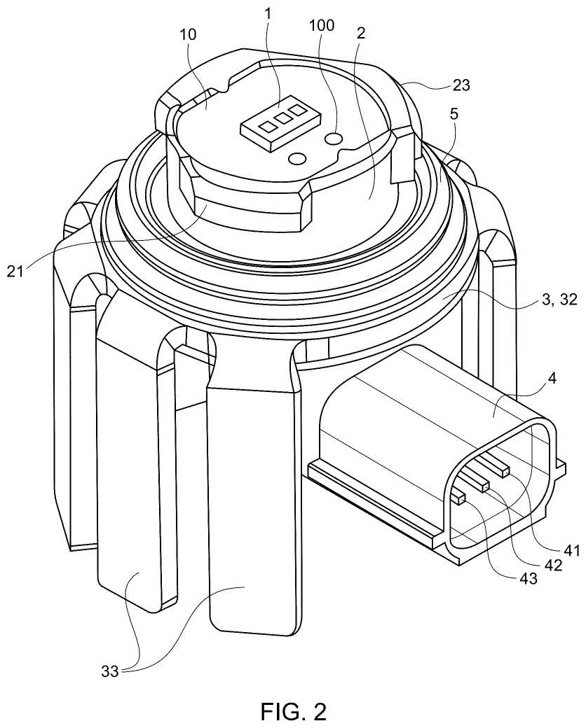

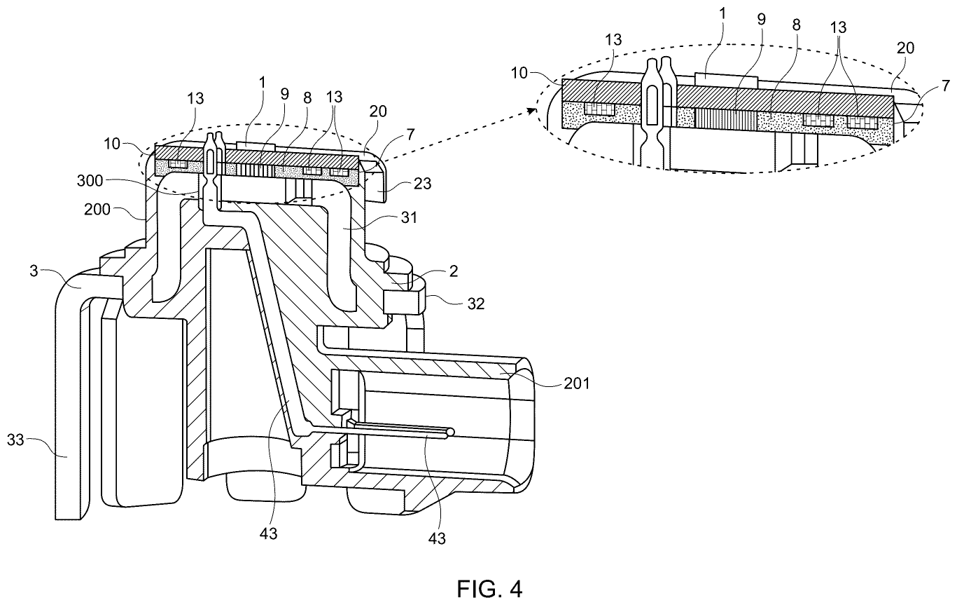

The holder 2 can, as shown in FIGS. 2 and 4, be designed, for example, as a single-piece plastic injection molded part and comprise a cylindrical first holder section 200 and a second holder section 201 designed as a socket, in which the ends of the electrical connections 41, 42, 43 are arranged as contact pins. This second holder section 201 forms the electrical connection element 4.

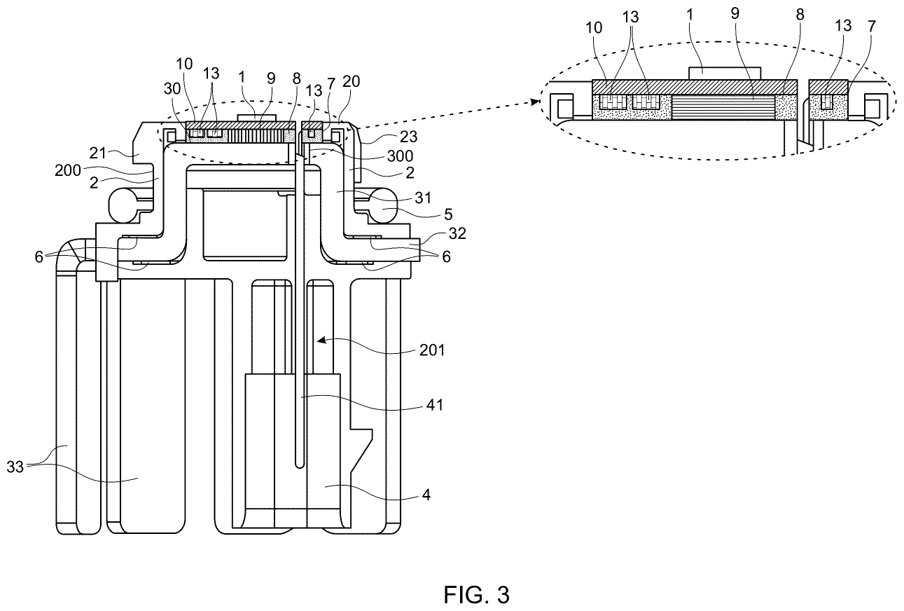

The holder 2, on the other hand, can also be formed by two separate plastic injection molded parts, as shown in FIGS. 1 and 3, namely a cylindrical first holder section 200 and a second holder section 201, in which the ends of the electrical connections 41, 42, 43, which are designed as contact pins, are arranged. Here too, the second holder section 201, or a part of the second holder section 201 designed as a socket, forms the electrical connection element 4.

In all the cases shown, the cylindrical first holder section 200 has a first recess 7 in which the mounting board 10 and a heat sink section 31 are arranged, and an end face with a flat, ring-shaped end surface 20, which serves as a reference plane for aligning the light-emitting diodes of the semiconductor light source arrangement 1 with respect to the holder 2 and with respect to the optical axis of the socket of a motor vehicle lamp into which the lighting device is inserted.

Three locking elements 21, 22, 23 are arranged along the outer circumference of the ring-shaped end face 20, which protrude radially from the outer surface of the cylindrical holder section 200 and form a bayonet lock with a correspondingly shaped counterpart of a socket of the motor vehicle lamp. To activate the bayonet lock, the lighting device is inserted into the socket of the motor vehicle lamp and then rotated clockwise or counterclockwise about the cylindrical axis of the cylindrical holder section 200. A locking element 23 comprises a stop for limiting the aforementioned rotational movement, which rests in the socket or mounting opening of the motor vehicle lamp after the bayonet lock. The mounting plate 10 with the semiconductor light source arrangement 1 mounted thereon is arranged inside the cylindrical holding section 200. The mounting plate 10 is arranged perpendicular to the cylinder axis of the cylindrical holder section 200. The cylindrical holder section 200 forms a receptacle on its outer surface for a sealing ring 5, which rests against the socket of a motor vehicle headlight after the lighting device has been installed.

The second holder section 201, which is designed as a socket, can be arranged at an angle to the cylinder axis of the cylindrical holder section 200, as shown in FIGS. 2 and 4. The ends of the electrical connections 41, 42, 43, which are designed as contact pins, are arranged in a plane perpendicular to the cylinder axis of the cylindrical holder section 200 inside the socket 201. The electrical connections 41, 42, 43 are made of metal and are embedded in sections in the plastic material of the holder 2, which is designed as a plastic injection molded part, so that their ends are freely accessible for electrical contact. A first end of the electrical connections 41, 42, 43 is each designed as a contact pin and arranged within the socket 201. A second end of the electrical connections 41, 42, 43 is each passed through an opening in the mounting board 10 and electrically contacted with a conductor track on the mounting board 10 in order to establish an electrical connection to the semiconductor light source arrangement 1.

The second holder section 201 can also be designed as a separate plastic injection molded part, as shown in FIGS. 1 and 3. The second holder section 201 also comprises three electrical contact pins 41, 42, 43, which are each made of metal and embedded in the plastic material of the second holder section 201. The second holder section 201 comprises a circular disc-shaped flange section which rests against an annular heat sink section 32 on the side facing away from the cylindrical first holder section 200. The flange section of the second holder section 201 is connected to the annular heat sink section 32 by adhesive 6. The adhesive 6 also serves as a sealant between the flange section of the second holder section 201 and the annular heat sink section 32, as well as between the cylindrical first holder section 200 and the annular heat sink section 32. For this purpose, the adhesive 6 is applied in a ring shape on both sides of the ring-shaped heat sink section 32. The second holder section 201 also comprises a section designed as a socket 4, which extends parallel to the ring axis of the retaining device 2 and is arranged parallel to and offset from this ring axis and is formed on the circular disc-shaped flange section. The free ends of the electrical contact pins 41, 42, 43 each extend into the socket 4 and serve there as electrical contacts for the lighting device and are intended for connecting a plug that can be plugged onto the socket 4. After the socket and plug are joined together, this connection can be sealed. The other ends of the three electrical contact pins 41, 42, 43 each protrude through the opening 300 in the support surface 30 of the heat sink 3 and form, for example, a press fit with the mounting board 10 and are each connected to an electrical contact on the mounting board 10. The electrical contact pins serve to supply power to the light-emitting diodes 11.

In all the cases shown, the heat sink 3 has a hollow cylindrical heat sink section 31 which is embedded in the plastic material of the holder 2 in the region of the cylindrical first holder section 200 or is adjacent thereto. On its side facing the end face 20 of the cylindrical first holder section 200, the hollow cylindrical heat sink section 31 comprises at least one flat surface 30 which is essentially parallel to the carrier. The cylinder axis of the hollow cylindrical heat sink section 31 is identical to the cylinder axis of the cylindrical first holder section 201, and the essentially parallel surface 30 is arranged perpendicular to the cylinder axis of the hollow cylindrical heat sink section 31.

The surface 30 of the hollow cylindrical heat sink section 31 comprises an opening 300 through which a second end of each of the three electrical connections 41, 42, 43 is passed. The second ends of the three electrical connections 41, 42, 43 form, for example, a press fit with the mounting board 10. Alternatively or in addition to the press fit, the second ends of the electrical connections 41, 42, 43 can also be connected to an electrical contact of the mounting board 10 by soldering.

The heat sink 3 also has a ring-shaped heat sink section 32 which is formed on the hollow cylindrical heat sink section 31 and whose ring axis coincides with the cylinder axis of the hollow cylindrical heat sink section 31. Cooling fins 33 are formed on the annular disc-shaped heat sink section 32 along its circumference. The cooling fins 33 are each angled at an angle of 90 degrees from the annular disc-shaped heat sink section 32 and each extend parallel to the ring axis of the annular disc-shaped heat sink section 32. The outer edge of the annular cooling body section 32 and the cooling fins 33 formed thereon protrude from the plastic material of the holder 2 or the cylindrical first holder section 200. The heat sink 3 is made of metal, for example stainless steel or sheet metal, and is designed as a single-piece deep-drawn bent part. The cooling fins 33 form a recess through which the second holder section 201, designed as a socket, extends in the embodiments shown in FIGS. 2 and 4. In the embodiments of FIGS. 1 and 3, the cooling fins 33 also form a recess, but this recess remains free to ensure, for example, accessibility of the socket 4.

As shown in FIGS. 3 and 4, in particular in the respective detailed views, the electronics 13 are arranged on a side of the mounting board 10 opposite the semiconductor light source arrangement 1. The semiconductor light source arrangement 1 is arranged on a side of the mounting board 10 facing away from the heat sink 3, and the electronics 13 for operating the semiconductor light source arrangement 1 is arranged on a side of the mounting board 10 facing the heat sink 3.

In addition, the heat sink 3 comprises a projection 9 in the region of the first recess 7, which extends centrally in the direction of the mounting board 10. The projection 9 can be formed integrally with the heat sink 3 or can be applied to the heat sink and connected thereto. The mounting board 10 is arranged in the first recess with the side on which the electronics 13 for operating the semiconductor light source arrangement 1 is arranged in such a way that the electronics 13 faces in the direction of the heat sink 3 and the mounting board rests at least partially on the projection 9. On the mounting board 10, the electronics 13 are arranged in an area around the projection 9, but not in the central area of the projection 9.

A thermally conductive layer 8 is arranged between the heat sink 3 and the mounting plate 10, which fills the area between the heat sink 3 and the mounting plate 10 and embeds the electronics 13 between the mounting plate 10 and the holder 2 and the heat sink 3. The height of the projection 9 is selected such that the highest component of the electronics 13 does not collide with the heat sink 3 when the mounting plate rests on the projection 9. The mounting plate comprises through-passages 100 through which the ends of the contact pins 41, 42, 43 are guided in order to additionally secure the mounting plate 10.

In the case shown in FIGS. 3 and 4, the holder 2 is designed such that the end face 20 is essentially flush with the surface of the mounting plate 10. However, this is only to be understood as an example, and the holder 2 may just as well be designed such that the end face 20 protrudes beyond both the mounting plate 10 and the semiconductor light source arrangement 1. This ensures additional protection for both the mounting plate 10 and the semiconductor light source arrangement 1.

Furthermore, the projection 9 can also be formed in the holder 2 or the first holder section 200 in the form of a circumferential or sectionally interrupted edge so that the mounting plate 10 can rest on it. This would allow, for example, electronic components to be arranged in the central area of the mounting plate 10.

To manufacture the lighting device shown schematically in FIGS. 2 and 4, the electrical connections 41, 42, 43, which are designed as contact pins, are inserted into one half of a plastic injection mold so that their ends protrude from the mold. The heat sink 3 is also inserted into this mold half so that parts of its hollow cylindrical section 31 and its ring-shaped section 32 are arranged in the mold half. The mold is then closed and plastic material is injected around the sections of the electrical connections 41, 42, 43 enclosed by the mold and around the parts of the heat sink sections 31, 32 arranged in the mold. In addition, after filling and allowing the plastic material to solidify, the mold of the plastic injection molding tool is used to form the holder 2 and, in particular, its cylindrical holder section 200 and its holder section 201, which is designed as a socket. The thermally conductive layer 8 is applied to the surface 30 protruding from the plastic material of the holder 2 and to the projection 9 of the heat sink 3, and the mounting board 10 provided with the semiconductor light source arrangement 1 and the electronic s 13 is fixed to the heat sink 3 and/or in the holder 2, for example by a press fit with the second ends of the contact pins 41, 42, 43 on the heat sink 3 or in the holder 2. This is done by pressing the mounting board 10 onto the thermally conductive layer 8 while it is still liquid or viscous, whereby the electronics 13 are embedded in the thermally conductive layer 8 by the pressure.

To produce the lighting device shown schematically in FIGS. 1 and 3, the individual components (first holder section 200, heat sink 3, and second holder section 201) are manufactured separately and then bonded together. Then, the thermally conductive layer 8 is applied to the surface 30 protruding from the plastic material of the holder 2 and to the projection 9 of the heat sink 3, and the mounting board 10 provided with the semiconductor light source arrangement 1 and the electronics 13 is fixed to the heat sink 3 or in the holder 2, for example by a press fit with the second ends of the contact pins 41, 42, 43 on the heat sink 3 or in the holder 2, respectively. This is done by pressing the mounting board 10 onto the thermally conductive layer 8 while it is still liquid or viscous, whereby the electronics 13 are embedded in the thermally conductive layer 8 by the pressure.

The invention is not limited to the embodiments described in detail above. For example, the holder 2 can be designed as a plastic injection molded part produced by means of a multi-stage plastic injection molding process. For example, during a first stage of the plastic injection molding process, the electrical connections 41, 42, 43 can be inserted into a first injection mold and surrounded by plastic so that, during the first stage of the process, the holder section 201 designed as a socket is formed with the electrical connections 41, 42, 43 fixed therein. Subsequently, the holder section 201 designed as a socket, together with the electrical connections 41, 42, 43 fixed therein and together with the heat sink 3, could be inserted into a second injection mold and overmolded with plastic to form the complete retaining device 2 with the additional cylindrical holder section 200. This two-stage plastic injection molding process has the advantage that the holder section 201 designed as a socket and the cylindrical holder section 200 can be made of different plastic materials.

The heat sink of the lighting device according to the invention can also have a heat sink section consisting of phase-changing material that changes its state of aggregation when heated. The heat sink section made of phase-changing material is, for example, completely enclosed in the plastic material of the holder and changes its state of aggregation when heated, for example from solid to liquid, and returns to the solid state when cooled.

The holder is made, for example, of polyamide (PA). In addition, the holder may be made of plastic material with high thermal conductivity to support the cooling function of the heat sink.

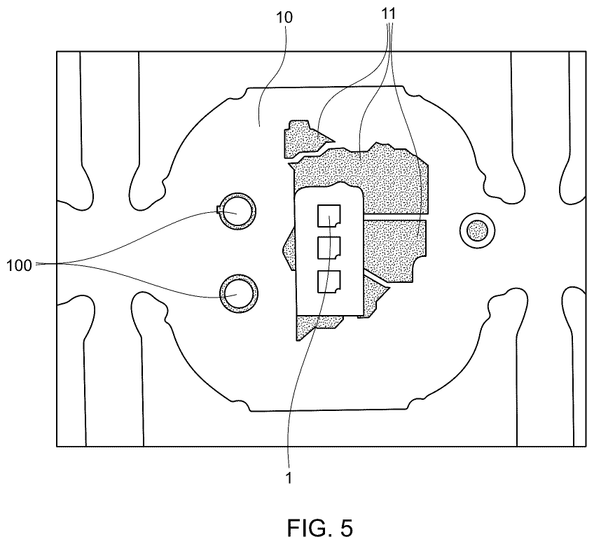

FIG. 5 shows a top view of a mounting board 10 according to some embodiments of the proposed principle. In the case shown, the mounting board 10 is still fixed in its manufacturing carrier. A semiconductor light source arrangement 1 comprising three light-emitting diodes is arranged on the upper side of the mounting board 10. In addition, the mounting board 10 has two passages 100 through which the ends of the contact pins 41, 42, 43 are guided in order to contact or fasten the mounting board 10. Furthermore, conductor tracks 11 are arranged on the mounting board 10, which connect the semiconductor light source arrangement 1 to electronics located on the underside of the mounting board 10.

1.-14. (canceled)

15. A lighting device comprising:
a semiconductor light source arrangement arranged on a carrier;
electronics configured for operating the semiconductor light source arrangement;
a heat sink configured for cooling the semiconductor light source arrangement;
an electrical connection element configured for supplying power to the semiconductor light source arrangement;
a thermally conductive layer; and
a holder,
wherein the carrier is arranged in a first recess of the holder,
wherein the heat sink forms at least one surface in the first recess, which is substantially parallel to the carrier, and
wherein the electronics are arranged on a side of the carrier opposite the semiconductor light source arrangement and are embedded in the thermally conductive layer between the carrier and the holder and/or the heat sink in the first recess.

16. The lighting device according to claim 15, wherein the carrier and/or the electronics are thermally coupled to the heat sink via the thermally conductive layer.

17. The lighting device according to claim 15, wherein the holder and/or the heat sink comprises at least one projection on which the carrier rests at least partially.

18. The lighting device according to claim 15, wherein the holder and/or the heat sink comprises at least one second recess in which the electronics are arranged.

19. The lighting device according to claim 15, wherein the thermally conductive layer has a thermal conductivity greater than or equal to 1.5 W/mK.

20. The lighting device according to claim 15, wherein the thermally conductive layer is free of silicone.

21. The lighting device according to claim 15, wherein the heat sink comprises:
a first heat sink section, which is arranged in the first recess of the holder and which forms, at least one surface which is substantially parallel to the carrier; and
a second heat sink section, which is arranged between the holder and the electrical connection element.

22. The lighting device according to claim 15, wherein the electrical connection element is formed integrally with the holder.

23. The lighting device according to claim 15, wherein the heat sink is formed integrally with the holder.

24. The lighting device according to claim 15, wherein the electrical connection element comprises electrical contacts which are guided through an opening through the heat sink.

25. The lighting device according to claim 15, further comprising locking elements arranged on the holder and configured to form a bayonet lock with a socket.

26. The lighting device according to claim 15, wherein the carrier is a mounting board.

27. The lighting device according to claim 15, wherein the holder is a plastic part.

28. A method for manufacturing a lighting device, the method comprising:
arranging a heat sink in a first recess of a holder;
connecting an electrical connection element to the holder;
applying a thermally conductive layer to an area of the holder and/or the heat sink within the first recess; and
pressing a carrier with a semiconductor light source arrangement arranged on a first side of the carrier and electronics for operating the semiconductor light source arrangement arranged on a second side opposite the first side onto the thermally conductive layer such that the electronics are embedded in the thermally conductive layer between the carrier and the holder and/or the heat sink.
